(19) United States
(12) Patent Application Publication
(10) Pub. No.: US 2008/0237860 A1
(43) Pub. Date: Oct. 2, 2008

(54) INTERCONNECT STRUCTURES CONTAINING A RUTHENIUM BARRIER FILM AND METHOD OF FORMING

(75) Inventors: Tadahiro Ishizaka, Watervliet, NY (US); Atsushi Gomi, Rensselaer, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 11/691,897

(22) Filed: Mar. 27, 2007

(51) Int. Cl. H01L 23/52; H01L 21/3205

(52) U.S. Cl. 257/751; 438/643; 257/E23.141; 257/E21.294

(57) ABSTRACT

Embodiments of the invention provide a method for integrating a Ru barrier film with good barrier properties into Cu metallization. The method includes exposing a substrate to a Ta-, Ti-, or W-containing precursor at a substrate temperature below the thermal decomposition temperature of the Ta-, Ti-, or W-containing precursor on the substrate to form a chemisorbed seed layer of partially decomposed Ta-, Ti-, or W-containing precursor on the substrate. The method further includes depositing a Ru barrier film on the chemisorbed seed layer, and forming bulk Cu metal on the Ru barrier film. According to additional embodiments, an interconnect structure and method of forming are provided.

### FIELD OF THE INVENTION

The invention relates to semiconductor processing, and more particularly to integration of a ruthenium barrier film into copper metallization structures, including interconnect structures for integrated circuits.

### BACKGROUND OF THE INVENTION

An integrated circuit contains various semiconductor devices and a plurality of conducting metal paths that provide electrical power to the semiconductor devices and allow these semiconductor devices to share and exchange information. Within an integrated circuit, metal layers are stacked on top of one another using intermetal or interlayer dielectric layers that insulate the metal layers from each other. Normally, each metal layer must form an electrical contact to at least one additional metal layer. Such electrical contact is achieved by etching a hole (i.e., a via) in the interlayer dielectric that separates the metal layers, and filling the resulting via with a metal to create an interconnect. Metal layers typically occupy etched pathways in the interlayer dielectric. A “via” normally refers to any micro-feature opening such as a hole, line or other similar feature formed within a dielectric layer that provides an electrical connection through the dielectric layer to a conductive layer underlying the dielectric layer. Similarly, micro-features containing metal layers connecting two or more vias are normally referred to as trenches.

A long-recognized objective in the constant advancement of integrated circuit (IC) technology is the scaling down of IC dimensions. Such scale down of IC dimensions reduces area capacitance and is critical to obtaining higher speed performance of ICs. Moreover, reducing the area of an IC die leads to higher yield in IC fabrication. These advances are driving forces to constantly scale down IC dimensions. An increase in device performance is normally accompanied by a decrease in device area or an increase in device density. An increase in device density requires a decrease in via dimensions used to form interconnects, including a larger aspect ratio (i.e., depth to width ratio). As the minimum feature dimensions on patterned substrates (wafers) steadily decreases, several consequences of this downward scaling are becoming apparent. As the width of metal lines are scaled down to smaller submicron and even nanometer (nm=10⁻⁹ m) dimensions, electromigration failure, which may lead to open and extruded metal lines, is now a well recognized problem. Moreover, as dimensions of metal lines further decrease, metal line resistivity increases substantially, and this increase in line resistivity may adversely affect circuit performance.

The introduction of copper (Cu) metal into multilayer metallization schemes for manufacturing integrated circuits is enabled by the damascene Cu plating process and is now extensively used by manufacturers of advanced microprocessors and application-specific circuits. However, Cu cannot be put in direct contact with dielectric materials since Cu has poor adhesion to the dielectric materials and Cu is known to easily diffuse into common integrated circuit materials such as silicon and dielectric materials where Cu is a mid-bandgap impurity. Furthermore, oxygen can diffuse from an oxygen-containing dielectric material into Cu, thereby decreasing the electrical conductivity of the Cu metal. Therefore, a diffusion barrier material is formed on dielectric materials and other materials in the integrated circuits to surround the Cu and prevent diffusion of the Cu into the integrated circuit materials.

A tantalum nitride/tantalum (TaN/Ta) bilayer is commonly used as a diffusion barrier/adhesion layer for Cu metallization since the TaN barrier layer adheres well to oxides and provides a good barrier to Cu diffusion and the Ta adhesion layer wets well to both TaN on which it is formed and to the Cu metal formed over it. However, TaN has high electrical resistivity and Ta is normally deposited by sputtering or plasma processing methods, which are unable to provide conformal coverage over high aspect ratio micro-features.

As the line width of interconnect structures is continually decreased, the thickness of the diffusion barrier/adhesion layer needs to be reduced to minimize the volume of the diffusion barrier/adhesion layer within a micro-feature opening containing the bulk Cu metal fill. Minimizing the volume of the diffusion barrier/adhesion layer in turn maximizes the volume of the bulk Cu metal fill. As is known to one of ordinary skill in the art, diffusion barrier materials generally have higher electrical resistivity than the bulk Cu metal fill. Therefore, maximizing the volume of the bulk Cu metal fill and minimizing the volume of the diffusion barrier/adhesion layer results in minimizing the electrical resistivity of the interconnect structure.

Ruthenium (Ru) metal has been suggested to replace the TaN/Ta bilayer layer since, unlike Ta, it may be conformally deposited and adheres well to Cu. However, thin conformal Ru barrier films with a thickness of only a few nanometers, have not shown acceptable barrier properties against Cu diffusion. Therefore, new processing methods are needed for integrating thin Ru films with good barrier properties into Cu metallization.

### SUMMARY OF THE INVENTION

A method is provided for integrating a Ru barrier film with good barrier properties into Cu metallization, for example, for interconnect structures in integrated circuits. Embodiments of the invention describe the use of a tantalum-containing (Ta-containing), titanium-containing (Ti-containing), or tungsten-containing (W-containing) seed layer located between a substrate and a Ru barrier film to improve the barrier properties of the Ru barrier film. Embodiments of the invention provide a Ru barrier film with a thickness less than about 10 nm.

According to one embodiment of the invention, the method includes exposing a substrate to a Ta-, Ti-, or W-containing precursor at a substrate temperature below the thermal decomposition temperature of the precursor on the substrate to form a chemisorbed seed layer of partially decomposed Ta-, Ti-, or W-containing precursor on the substrate, depositing a Ru barrier film on the chemisorbed seed layer; and forming bulk Cu metal on the Ru barrier film.

According to another embodiment of the invention, a method is provided for forming an interconnect structure. The method includes providing a substrate containing a micro-feature opening formed within a dielectric material, where the micro-feature opening comprises a via, a trench, or a combination thereof, and exposing the substrate to a Ta(NMe₂)₃(NCMe₂Et) (TAIMATA) precursor at a substrate temperature below about 250° C. to form a chemisorbed seed layer of partially decomposed TAIMATA on the substrate. The method further includes depositing a Ru barrier film on the chemisorbed seed layer by exposure to a Ru₃(CO)₁₂ and CO carrier gas, sputter depositing a Cu seed layer on the Ru barrier film, and filling the micro-feature opening with bulk Cu metal by a Cu plating process. According to one embodiment, the chemisorbed seed layer and the Ru barrier film are at least partially removed from a bottom of the micro-feature prior to the sputter depositing.

According to one embodiment, an interconnect structure is provided. The interconnect structure includes a substrate containing a micro-feature opening formed within a dielectric material, a Ta-, Ti-, or W-containing seed layer of a partially decomposed Ta-, Ti-, or W-containing precursor in the micro-feature opening, a Ru barrier film on the seed layer; and bulk Cu metal filling the micro-feature opening.

### BRIEF DESCRIPTION OF THE DRAWINGS

In the drawings:

FIGS. 1A-1E schematically show cross-sectional views of forming a film structure for Cu metallization according to an embodiment of the invention;

FIG. 2 is a flow diagram for forming a film structure for Cu metallization according to an embodiment of the invention;

FIG. 3A shows sheet resistance results for different film structures according to embodiments of the invention;

FIG. 3B shows barrier test results in tabular form from the sheet resistance data in FIG. 3A;

FIGS. 4A-4F schematically show cross-sectional views of forming interconnect structures according to embodiments of the invention; and

FIGS. 5A and 5B schematically show cross-sectional views of additional interconnect structures according to embodiments of the invention.

### DETAILED DESCRIPTION OF SEVERAL EMBODIMENTS OF THE INVENTION

Embodiments of the invention provide a method for integrating thin Ru films with good barrier properties into Cu metallization structures, for example interconnect structures for integrated circuits. The Ru barrier films may replace the conventional TaN/Ta bilayer structure while providing better film uniformity inside micro-features and reduced film thickness, thereby maximizing the volume of the bulk Cu metal fill in the interconnect structure and minimizing the electrical resistivity of the integrated circuit.

The current inventors have recognized that an ultra-thin seed layer formed between a substrate and a Ru barrier film greatly improves the diffusion barrier properties of the Ru barrier film. According to embodiments of the invention, the seed layer contains a chemisorbed layer of partially decomposed Ta-, Ti-, or W-containing precursor on a substrate, and a Ru barrier film with a thickness of less than about 10 nm is deposited on the seed layer. Many current and future interconnect structures require diffusion barrier films to have a thickness less than about 10 nm, for example less than about 5 nm, or less than about 3 nm, in order to maximize the volume of a bulk Cu metal fill in a micro-feature.

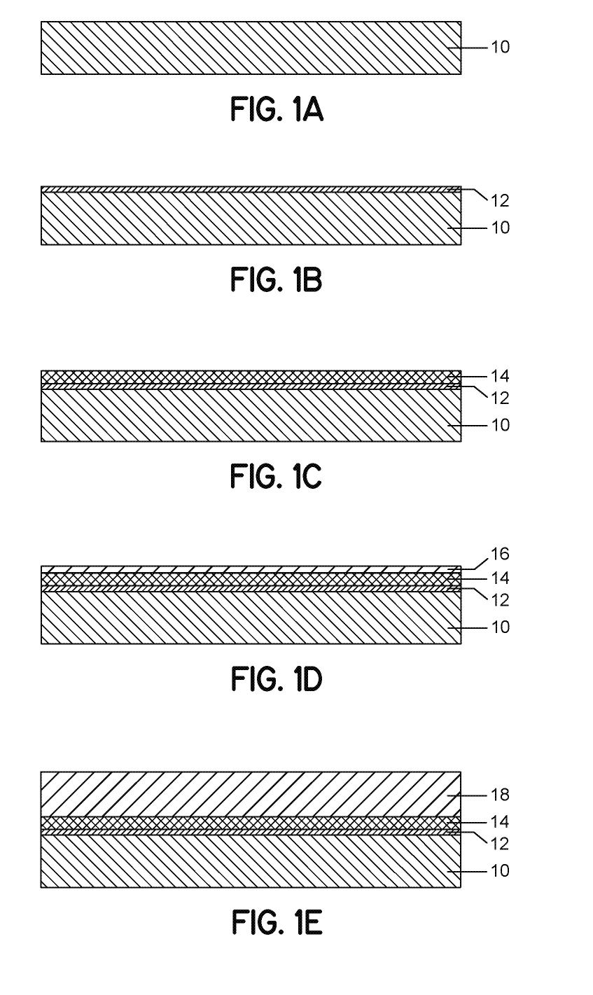

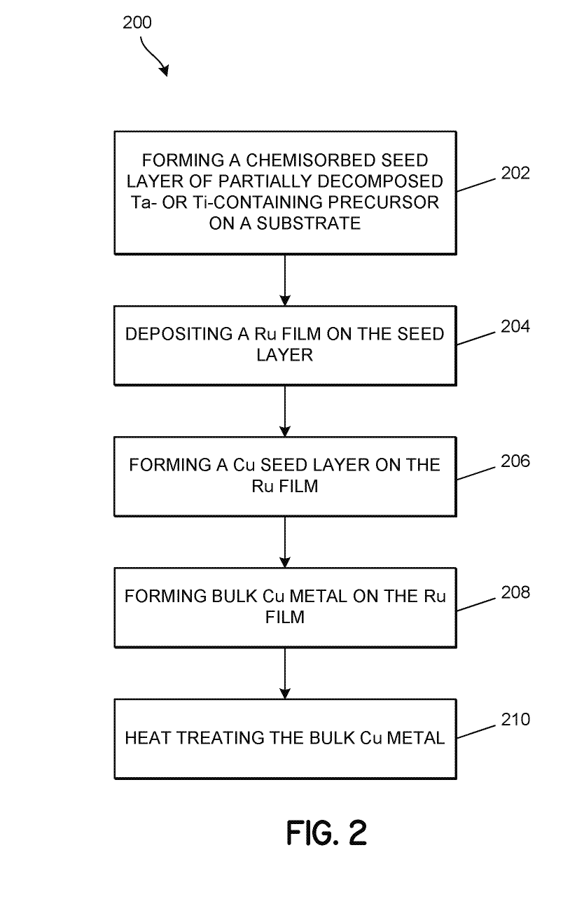

FIGS. 1A-1E schematically show cross-sectional views of forming a film structure for Cu metallization according to an embodiment of the invention, and FIG. 2 is a flow diagram according to an embodiment of the invention.

FIG. 1A schematically shows a substrate 10, for example a Si substrate or a dielectric material. The dielectric material may contain SiO₂, SiON, SiN, or a low dielectric constant (low-k) material having a dielectric constant less than that of SiO₂(k˜3.9). Common low-k materials can contain simple or complex compounds of Si, O, N, C, H, or halogens, either as dense or porous materials.

FIG. 1B schematically shows a chemisorbed seed layer 12 containing partially decomposed Ta-, Ti-, or W-containing precursor on the substrate 10. The seed layer 12 is formed in step 202 of the process 200 of FIG. 2 by exposing the substrate to a Ta-, Ti-, or W-containing precursor at a substrate temperature below the thermal decomposition temperature of the Ta-, Ti-, or W-containing precursor on the substrate. Since the substrate is maintained at a temperature below the thermal decomposition temperature, the formation of the seed layer 12 is self-limiting, where the deposition stops when the thickness of the seed layer 12 corresponds to about one adsorbed layer or less of the partially decomposed precursor.

As is well known to those skilled in the art, chemisorption refers to formation of a chemical bond between a precursor (e.g., a Ta-, Ti-, or W-containing precursor) and a substrate upon exposure of the precursor to the substrate. Chemisorption is often associated with a partially decomposed precursor adsorbed on a substrate, where an intra-molecular precursor bond is broken and becomes available for chemical bonding to the substrate. Chemisorption is different from physisorption, which refers to the weakest form of adsorption resulting from purely physical attraction (van der Waals force) between a precursor and the substrate, without a chemical bond being formed between the precursor and the substrate.

According to embodiments of the invention, the thermal decomposition temperature of a Ta-, Ti-, or W-containing precursor may be determined by experimentation or obtained from the literature. In one example, the Ta-containing precursor may include Ta(NMe₂)₃(NCMe₂Et) (TAIMATA). The thermal decomposition temperature of TAIMATA has previously been determined to be about 250° C. Below about 250° C., exposure of a substrate to TAIMATA forms seed layer 12 in a self-limiting process, where the substrate surface becomes saturated with partially decomposed precursor. Such a self-limiting process is commonly used to deposit material in atomic layer deposition (ALD) processing, where a first reactant and a second reactant are alternately and sequentially exposed to a substrate. Above about 250° C., continuous exposure to TAIMATA forms a Ta-containing film in a chemical vapor deposition (CVD) mode where the film thickness is proportional to exposure time.

A wide variety of Ta-, Ti-, or W-containing precursors may be utilized for depositing the seed layer 12. In addition to TAIMATA, other examples of Ta-containing precursors containing “Ta—N” intra-molecular bonds include Ta(NEt₂)₅ (PDEAT), Ta(NMe₂)₅ (PDMAT), Ta(NEtMe)₅ (PEMAT), (tBuN)Ta(NMe₂)₃ (TBTDMT), (tBuN)Ta(NEt₂)₃ (TBTDET), (tBuN)Ta(NEtMe)₃ (TBTEMT), and (iPrN)Ta(NEt₂)₃ (IPTDET). Other examples of Ta-containing precursors contain “Ta—C” intra-molecular bonds, for example Ta(η⁵-C₅H₅)₂H₃, Ta(CH₂)(CH₃)(η⁵-C₅H₅)₂, Ta(η³-C₃H₅) (η⁵-C₅H₅)₂, Ta(CH₃)₃(η⁵-C₅H₅)₂, Ta(CH₃)₄(η⁵ -C₅(CH₃)₅), or Ta(η⁵-C₅(CH₃)₅)₂H₃. Other Ta-containing precursors contain “Ta—O” intra-molecular bonds, for example Ta₂(OEt)₁₀ and (Me₂NCH₂CH₂O)Ta(OEt)₄. TaCl₅ and TaF₅ are examples of tantalum halide precursors containing “Ta-halogen” bonds.

Representative examples of Ti-containing precursors having “Ti—N” intra-molecular bonds include Ti(NEt₂)₄ (TDEAT), Ti(NMeEt)₄ (TEMAT), Ti(NMe₂)₄ (TDMAT). Representative examples of Ti-containing precursors containing “Ti—C” intra-molecular bonds include Ti(COCH₃)(η⁵-C₅H₅)₂Cl, Ti(η⁵-C₅H₅)Cl₂, Ti⁵-C₅H₅)Cl₃, Ti(η⁵-C₅H₅)₂Cl₂, Ti(η⁵-C₅(CH₃)₅)Cl₃, Ti(CH₃)(η⁵-C₅H₅)₂Cl, Ti(η⁵-C₉H₇)₂Cl₂, Ti((η⁵-C₅(CH₃)₅)₂Cl, Ti((η⁵-C₅(CH₃)₅)₂Cl₂, Ti(η⁵-C₅H₅)₂(μ-Cl)₂, Ti(η⁵-C₅H₅)₂(CO)₂, Ti(CH₃)₃(η⁵-C₅H₅), Ti(CH₃)₂(η⁵-C₅H₅)₂, Ti(CH₃)⁸-C₈H₈), Ti(C₅H₅)₂(η⁵-C₅H₅)₂, Ti((C₅H₅)₂)₂(η-H)₂, Ti(η⁵-C₅(CH₃)₅)₂, Ti(η⁵-C₅(CH₃)₅)₂(H)₂, and Ti(CH₃)₂(η⁵-C₅(CH₃)₅)₂. TiCl₄ is an example of a titanium halide precursor containing a “Ti-halogen” bond.

Representative examples of tungsten-containing (W-containing) precursors include W(CO)₆, which contains a “W—C” intra-molecular bond, and WF₆, which contains a “W-halogen” intra-molecular bond.

FIG. 1C schematically shows a Ru barrier film 14 deposited in step 204 on the seed layer 12. A thickness of the Ru barrier film 14 can, for example, be less than about 10 nm, for example about 5 nm, about 4 nm, about 3 nm, or about 2 nm. In one example, the Ru barrier film 14 may be deposited by a CVD process at a substrate temperature of about 180° C. utilizing a Ru₃(CO)₁₂ precursor and a CO carrier gas. An exemplary Ru CVD process using a Ru₃(CO)₁₂ precursor and a CO carrier gas is described U.S. patent application Ser. No. 10/996,145, entitled METHOD AND DEPOSITION SYSTEM FOR INCREASING DEPOSITION RATES OF METAL LAYERS FROM METAL-CARBONYL PRECURSORS, the entire content of which is herein incorporated by reference. In additional examples, the Ru barrier film 14 may be deposited by a CVD process utilizing a ruthenium metalorganic precursor. Exemplary ruthenium metalorganic precursors include (2,4-dimethylpentadienyl) (ethylcyclopentadienyl) ruthenium (Ru(DMPD)(EtCp)), bis(2,4-dimethylpentadienyl) ruthenium (Ru(DMPD)₂), 4-dimethylpentadienyl) (methylcyclopentadienyl) ruthenium (Ru(DMPD)(MeCp)), and bis(ethylcyclopentadienyl) ruthenium (Ru(EtCp)₂), as well as combinations of these and other precursors. Other examples for depositing the Ru barrier film 14 include ALD processing and sputtering methods using a solid Ru metal target.

According to one embodiment of the invention, steps 202 and 204 may be performed at the same or similar substrate temperature. In one example, a Ta-containing seed layer 12 may formed on the substrate 10 at a substrate temperature of about 180° C. by exposure of TAIMATA to the substrate 10, and the Ru barrier film 14 may be formed on the seed layer 12 by exposure of a Ru₃(CO)₁₂ precursor and a CO carrier gas at the same or similar substrate temperature.

According to one embodiment of the invention, the deposited Ru barrier film 14 may be heat treated at a temperature between about 100° C. and about 400° C. During the heat treating, the Ru barrier film 14 may be exposed to an inert gas, H₂, or a combination of an inert gas and H₂. The inert gas can, for example, be selected from a noble gas such as Ar and N₂. An exemplary combination includes 10:1 H₂:Ar. Exemplary heat treatments of the Ru barrier film 14 include gas pressure of 3 Torr and process time of 30 minutes, but embodiments of the invention are not limited by these processing conditions as other heat treating conditions may be utilized. For example, the gas pressure can be between about 1 Torr and about 760 Torr, or between about 10 Torr and about 100 Torr.

FIG. 1D schematically shows a Cu seed layer 16 deposited on the Ru barrier film 14 in step 206. The Cu seed layer 16 provides a Cu growth surface for a subsequent Cu plating process. A thickness of the Cu seed layer 16 can, for example, be between about 0.5 nm and about 20 nm, or between about 1 nm and about 3 nm, for example about 2 nm. The Cu seed layer 16 may be deposited by sputtering methods, for example by ionized physical vapor deposition (IPVD). An exemplary IPVD system is described in U.S. Pat. No. 6,287,435. In one example, the Cu seed layer 16 may be deposited using a capacitively coupled plasma (CCP) system where a Cu sputtering target forms an upper electrode and a substrate holder upon which the substrate 10 is positioned forms a lower electrode. However, other types of plasma systems can be used.

FIG. 1E schematically shows a bulk Cu metal 18 formed on the Ru barrier film 14 in step 208. Bulk Cu metal deposition processes are well known by one of ordinary skill in the art of circuit fabrication and can, for example, include an electrochemical plating process or an electroless plating process on the Cu seed layer 16, thereby forming the bulk Cu metal 18. Commonly, bulk Cu metal deposition is followed by a chemical mechanical polishing (CMP) process to planarize and remove excess Cu metal. Other bulk Cu metal deposition processes are also available, for example Cu sputtering processes. Alternatively, bulk Cu metal 18 may be directly plated onto the Ru barrier film 14.

According to one embodiment of the invention, the bulk Cu metal 18 may be heat treated in step 210 at a temperature between about 100° C. and about 400° C. following the Cu plating process. During the heat treating, the bulk Cu metal 18 may be exposed to H₂ or a combination of an inert gas and H₂. The inert gas can, for example, be selected from a noble gas such as Ar and N₂. A combination of the inert gas and H₂ can, for example, include forming gas, which commonly contains 1-10% H₂, balance N₂. Exemplary heat treatments of the bulk Cu metal 18 include gas pressure of 650 Torr and process time of 30 minutes, but embodiments of the invention are not limited by these heat treating conditions as other processing conditions may be utilized. For example, the gas pressure can be between about 1 Torr and about 760 Torr, or between about 10 Torr and about 100 Torr.

According to an embodiment of the invention, the Ru barrier film 14, the bulk Cu metal 18, or both the Ru barrier film 14 and the bulk Cu metal 18 may be heat treated in separate steps as described above. The heat treating steps may use the same or similar temperatures and gaseous environments, for example temperatures between about 100° C. and 400° C. and forming gas environments.

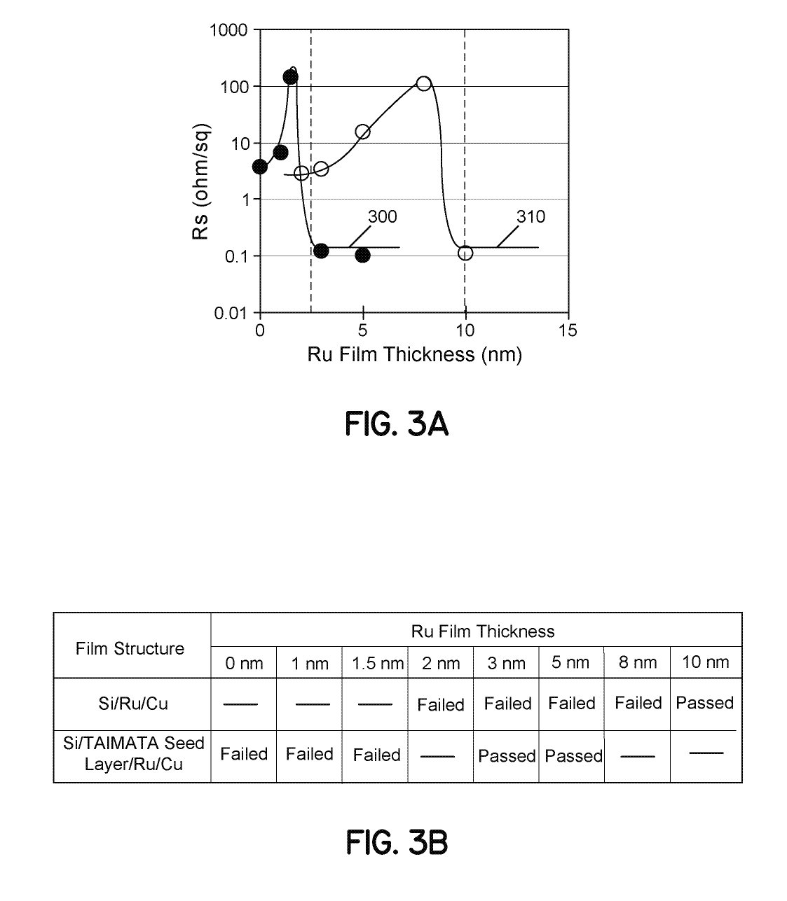

FIG. 3A shows sheet resistance results for different film structures according to embodiments of the invention, and FIG. 3B shows barrier test results in tabular form from the sheet resistance data in FIG. 3A. The sheet resistance was measured using a 4-point probe. Different test structures containing Si/TAIMATA seed layer/Ru/Cu, as depicted in FIG. 1E, were prepared and measured. In order to evaluate the effect of the TAIMATA seed layer on the barrier properties of the Ru barrier film, Si/Ru/Cu test structures without a TAIMATA seed layer were prepared and measured. The Ru films had thicknesses between 0 nm (no Ru film) and 10 nm.

Still referring to FIGS. 1A-1E, Si/TAIMATA seed layer/Ru/Cu test structures were prepared by degassing the Si substrate 10 at 250° C. in an Ar gas environment under reduced pressure conditions. Next a TAIMATA seed layer 12 was formed on a Si substrate 10 by exposing the substrate to TAIMATA at a substrate temperature of 180° C., which is below the thermal decomposition temperature of TAIMATA on Si, as described above. Next, a Ru barrier film 14 was deposited on the seed layer 12 by CVD at a substrate temperature of 180° C. utilizing a Ru₃(CO)₁₂ precursor and a CO carrier gas. Thereafter, a 150 nm thick bulk Cu metal 18 was sputter deposited onto the Ru barrier film 14. Upon deposition of the bulk Cu metal 18, the test structures were transported in air to a vacuum annealing system where they were annealed in a N₂ gas environment under reduced pressure conditions at 400° C. for 30 min. These are common test conditions for screening new barriers and evaluating barrier properties in Cu metallization.

In FIG. 3A, curves 300 and 310 show the measured Rs values for the Si/TAIMATA seed layer/Ru/Cu and Si/Ru/Cu test structures, respectively. As seen in curve 300, the Si/TAIMATA seed layer/Ru/Cu film structures did provide adequate resistance against Cu diffusion at a Ru barrier film thickness of 3 nm and greater, as indicated by the low Rs values. However, the Ru barrier film failed at a film thickness of 1.5 nm and lower, as indicated by formation of high resistivity copper silicides due to diffusion of Cu through the Ru barrier film into the Si substrate. In comparison, curve 310 shows that Si/Ru/Cu test structures having a Ru barrier film thickness less than 10 nm did not provide adequate resistance against Cu diffusion. These results are summarized in tabular form in FIG. 3B.

The results in FIGS. 3A and 3B demonstrate that a film structure containing a TAIMATA seed layer and an ultra-thin Ru barrier film can be utilized as a diffusion barrier for Cu metallization using a Ru film thickness of only 3 nm. In comparison, a film structure where a TAIMATA seed layer is omitted, requires a Ru film thickness of at least about 10 nm. Thus, embodiments of the invention allow integration of Ru barrier films into micro-features where a thickness of less than about 10 nm is required for the Ru barrier film. For example, barrier film thicknesses required for M1 metal lines in integrated circuits are projected to be about 3.3 nm, 2.4 nm, and 1.7 nm for micro-feature widths (pitches) of 90 nm, 64 nm, and 44 nm, respectively.

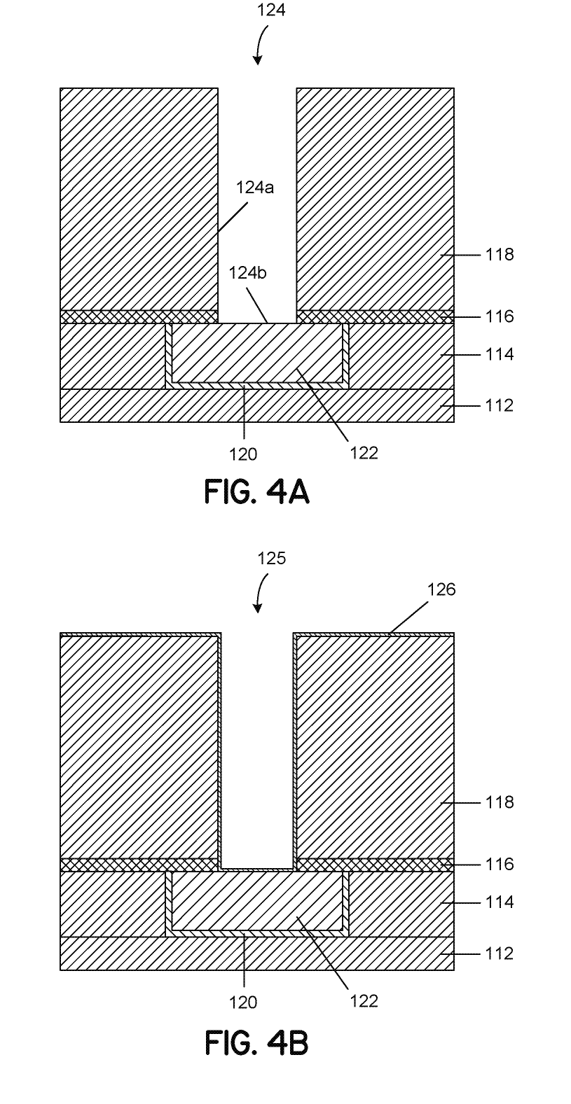

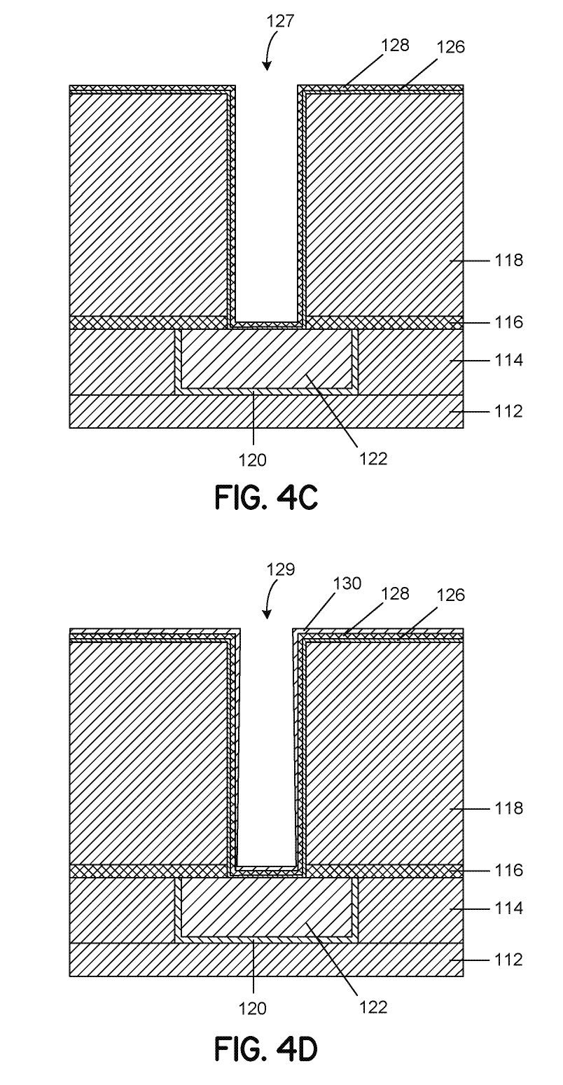

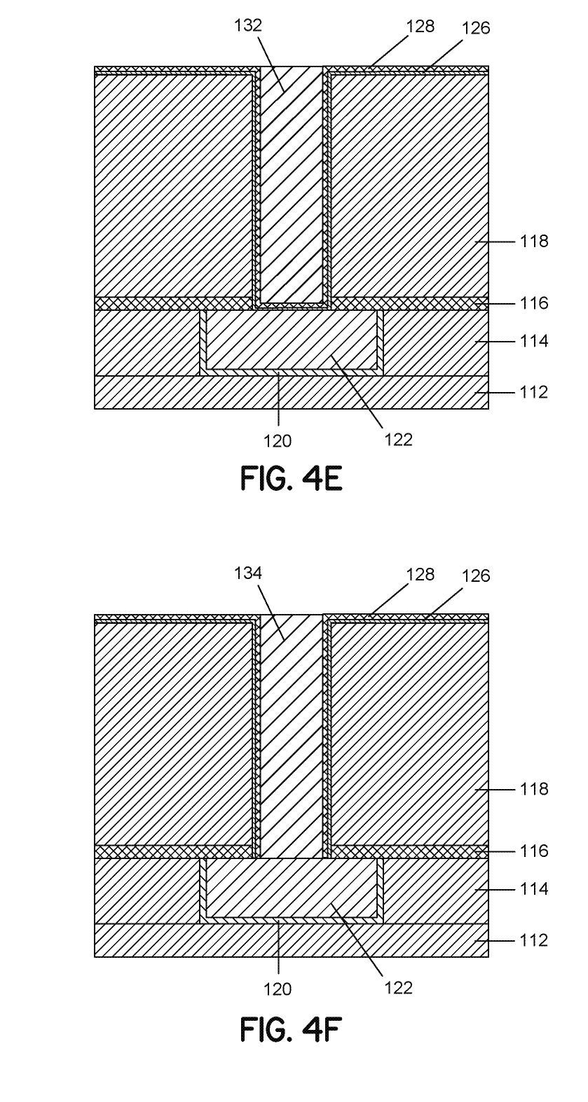

FIGS. 4A-4F schematically show cross-sectional views for forming low resistivity Cu interconnect structures according to embodiments of the invention. FIG. 4A schematically shows a cross-sectional view of an interconnect structure having a micro-feature opening 124 formed in dielectric material 118 over a conductive interconnect structure 122. The micro-feature opening 124 includes sidewall and bottom surfaces 124a and 124b, respectively. The interconnect structure further contains dielectric layers 112 and 114, a barrier layer 120 surrounding the conductive interconnect structure 122, and an etch stop layer 116. The conductive interconnect structure 122 can, for example, contain Cu or W.

According to an embodiment of the invention, the micro-feature opening 124 can be a via having an aspect ratio (depth/width) greater than or equal to about 2:1, for example 3:1, 4:1, 5:1, 6:1, 12:1, 15:1, or higher. The via can have widths of about 200 nm or less, for example 150 nm, 90 nm, 64 nm, 44 nm, 32 nm, 20 nm, or lower. However, embodiments of the invention are not limited to these aspect ratios or via widths, as other aspect ratios and via widths may be utilized.

In FIG. 4B, a Ta-, Ti-, or W-containing seed layer 126 is deposited on the interconnect structure, including on the sidewall and bottom surfaces 124a and 124b of the micro-feature opening 124 to form micro-feature opening 125.

In FIG. 4C, a Ru barrier film 128 is deposited on the seed layer 126 to form micro-feature opening 127. A thickness of the Ru barrier film 128 can, for example, be less than about 10 nm, for example about 5 nm, about 4 nm, about 3 nm, or about 2 nm. According to one embodiment of the invention, the Ru barrier film 128 may be heat treated at a temperature between about 100° C. and about 400° C. During the heat treating, the Ru barrier film 128 may be exposed to an inert gas, H₂, or a combination of an inert gas and H₂.

In FIG. 4D, a Cu seed layer 130 is deposited over the interconnect structure form micro-feature opening 129. The Cu seed layer 130 may be non-conformally deposited over the interconnect structure with a minimum thickness on the sidewalls of the micro-feature. The Cu seed layer 130 may be utilized as a Cu growth surface for a subsequent Cu plating process. According to one embodiment of the invention, the Cu seed layer 130 may be deposited on a Ru barrier film 128 following a heat treatment of the Ru film described above. A thickness of the Cu seed layer 130 can be between about 0.5 nm and about 20 nm, or between about 1 nm and about 3 nm, for example about 2 nm.

In FIG. 4E, the micro-feature opening 129 is filled with bulk Cu metal 132 and excess Cu metal removed by a CMP process. Although not shown in FIG. 4E, the CMP process may at least partially remove the Ru barrier film 128 and the seed layer 126 from the field area of the interconnect structure. Alternatively, bulk Cu metal 132 may be directly plated onto the Ru barrier film 128.

According to another embodiment of the invention, the Ru barrier film 128 and the seed layer 126 at the bottom of the micro-feature opening 127 depicted in FIG. 4C may be at least partially removed by a sputter removal process prior to deposition of the Cu seed layer 130, in order to reduce the resistivity between the bulk Cu metal and the conductive interconnect structure 122. FIG. 4F shows an interconnect structure where the Ru barrier film 128 and the seed layer 126 at the bottom of the micro-feature opening 127 have been completely removed prior to deposition of the Cu seed layer 130 and the bulk Cu metal 134, thereby directly contacting the bulk Cu metal 134 and the conductive interconnect structure 122 which reduces the resistivity of the interconnect structure in FIG. 4F compared to that of the interconnect structure depicted in FIG. 4E. Although not shown in FIG. 4F, removal of the Ru barrier film 128 and the seed layer 126 from the bottom of the micro-feature opening 124 may at least partially remove the Ru barrier film 128 and the seed layer 126 from other surfaces of the interconnect structure, such as the field area and sidewalls of the micro-feature.

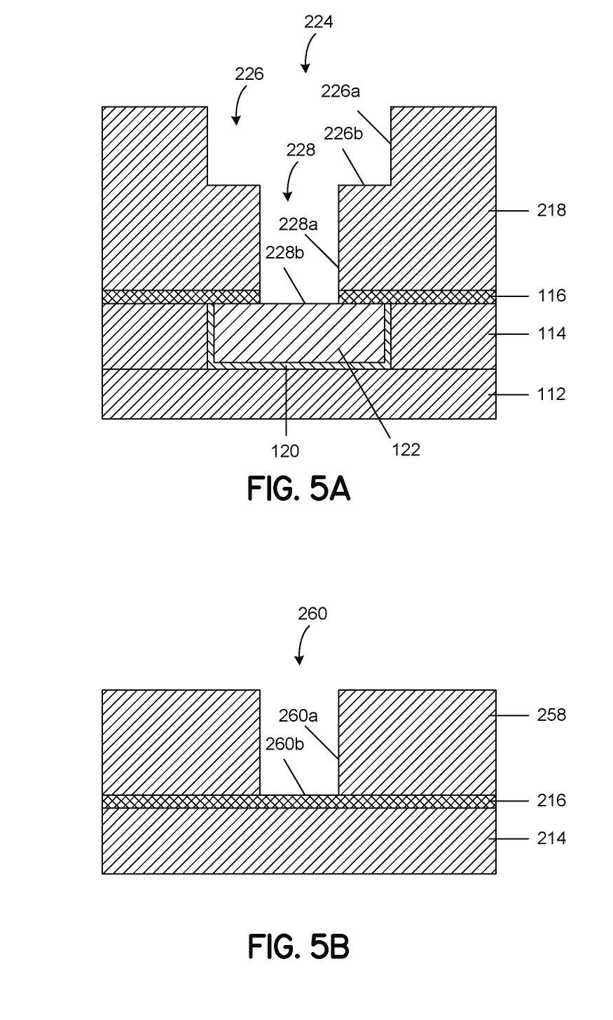

An exemplary micro-feature opening 124 was illustrated and described above in FIG. 4A, but embodiments of the invention may be applied to other types of micro-feature openings found in integrated circuit design. FIGS. 5A-5B schematically show cross-sectional views of other interconnect structures according to additional embodiments of the invention. As will be appreciated by one of ordinary skill in the art, embodiments of the invention can be readily applied to the interconnect structures depicted in FIGS. 5A and 5B.

FIG. 5A schematically shows a cross-sectional view of a dual damascene interconnect structure. Dual damascene interconnects are well known by one of ordinary skill in the art of integrated circuit fabrication. The interconnect structure depicted in FIG. 5A is similar to the interconnect structure depicted in FIG. 4A but contains a dual damascene interconnect opening 224 formed over conductive interconnect structure 122. The dual damascene interconnect opening 224 contains a via 228 having sidewall and bottom surfaces 228a and 228b, respectively, and a trench 226 formed in dielectric material 218, where the trench 226 contains sidewall and bottom surfaces 226a and 226b, respectively. The trench 226 may be used for an upper conductive interconnect structure and the via 228 connects the trench 226 to the conductive interconnect structure 122. The interconnect structure further contains dielectric layers 112 and 114, barrier layer 120 surrounding the conductive interconnect structure 122, and etch stop layer 116. In accordance with embodiments of the invention, Ta-, Ti-, or W-containing seed layer 126 may be deposited on the sidewall and bottom surfaces of the trench 226 and via 228.

FIG. 5B schematically shows a cross-sectional view of an interconnect structure according to one embodiment of the invention. The interconnect structure contains a micro-feature opening (e.g., a trench) 260 within dielectric material 258. The micro-feature opening 260 includes sidewall and bottom surfaces 260a and 260b, respectively. The interconnect structure further contains dielectric layer 214 and etch stop layer 216. In accordance with embodiments of the invention, Ta-, Ti-, or W-containing seed layer 126 may be deposited on the sidewall 260a and on the bottom surface 260b in contact with the etch stop layer 216.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

It should be apparent from the discussion above, embodiments of the invention can provide structures containing a Ta-, Ti-, or W-containing seed layer on a substrate and a thin Ru barrier film that provides good barrier properties for Cu metallization. Furthermore, the Ta-, Ti-, or W-containing seed layers and Ru films may be conformally deposited to meet current and future requirements of high aspect ratio structures in integrated circuits.

What is claimed is:

1. A method for processing a substrate, the method comprising:
exposing the substrate to a Ta-, Ti-, or W-containing precursor at a substrate temperature below a thermal decomposition temperature of the precursor on the substrate to form a chemisorbed seed layer of partially decomposed Ta-, Ti-, or W-containing precursor on the substrate;
depositing a Ru barrier film on the chemisorbed seed layer; and
forming bulk Cu metal on the Ru barrier film.

2. The method of claim 1, wherein a thickness of the Ru barrier film is less than about 10 nm.

3. The method of claim 1, wherein a thickness of the Ru barrier film is between about 2 nm and about 8 nm.

4. The method of claim 1, wherein a thickness of the Ru barrier film is between about 3 nm and about 5 nm.

5. The method of claim 1, wherein the exposing is to a Ta-containing precursor, and wherein an intra-molecular bond in the Ta-containing precursor comprises a Ta—N chemical bond, a Ta—C chemical bond, a Ta—O chemical bond, or a Ta-halogen chemical bond.

6. The method of claim 5, wherein the Ta-containing precursor comprises Ta(NMe₂)₃(NCMe₂Et) (TAIMATA), Ta(NEt₂)₅ (PDEAT), Ta(NMe₂)₅ (PDMAT), Ta(NEtMe)₅ (PEMAT), (tBuN)Ta(NMe₂)₃ (TBTDMT), (tBuN)Ta(NEt₂)₃ (TBTDET), (tBuN)Ta(NEtMe)₃ (TBTEMT), (iPrN)Ta(NEt₂)₃ (IPTDET), Ta(η⁵-C₅H₅)₂H₃, Ta(CH₂)(CH₃)(η⁵-C₅H₅)₂, Ta(η³-C₃H₅) (η⁵-C₅H₅)₂, Ta(CH₃)₃(η⁵-C₅H₅)₂, Ta(CH₃)₄(η⁵-C₅(CH₃)₅), Ta(η⁵-C₅(CH₃)₅)₂H₃, Ta₂(OEt)₁₀, (Me₂NCH₂CH₂O)Ta(OEt)₄, TaCl₅, or TaF₅.

7. The method of claim 1, wherein the exposing is to a Ti-containing precursor, and wherein an intra-molecular bond in the Ti-containing precursor comprises a Ti—N chemical bond, a Ti—C chemical bond or a Ti-halogen chemical bond.

8. The method of claim 7, wherein the Ti-containing precursor comprises Ti(NEt₂)₄, (TDEAT), Ti(NMeEt)₄ (TEMAT), Ti(NMe₂)₄ (TDMAT). Ti(COCH₃) (η⁵-C₅H₅)₂Cl, Ti(η⁵-C₅H₅)Cl₂, Ti(η⁵-C₅H₅)Cl₃, Ti(η⁵-C₅H₅)₂Cl₂, Ti(η⁵-C₅(CH₃)₅)Cl₃, Ti(CH₃)(η⁵-C₅H₅)₂Cl, Ti(η⁵-C₉H₇)₂Cl₂, Ti((η⁵-C₅(CH₃)₅)₂Cl, Ti (η⁵-C₅(CH₃)₅)₂Cl₂, Ti(η⁵-C₅H₅)₂(μ-Cl)₂, Ti(η⁵-C₅H₅)₂(CO)₂, Ti(CH₃)₃(η⁵-C₅H₅), Ti(CH₃)₂(η⁵-C₅H₅)₂, Ti(CH₃)₄, Ti(η⁵-C₅H₅)(η⁷-C₇H₇), Ti(η⁵-C₅H₅)(η⁸-C₈H₈), Ti(C₅H₅)₂(η⁵-C₅H₅)₂, Ti(C₅H₅)₂)₂(η-H)₂, Ti(η⁵C₅(CH₃)₅)₂, Ti(η⁵-C₅(CH₃)₅)₂(H)₂, Ti(CH₃)₅)₂, or TiCl₄.

9. The method of claim 1, wherein the exposing is to a W-containing precursor, and wherein the W-containing precursor comprises W(CO)₆ or WF₆.

10. The method of claim 1, wherein the substrate is maintained at substantially the same temperature during the exposing and the depositing.

11. The method of claim 1, wherein the depositing comprises:
exposing the seed layer to Ru₃(CO)₁₂, (2,4-dimethylpentadienyl) (ethylcyclopentadienyl) ruthenium (Ru(DMPD)(EtCp)), bis(2,4-dimethylpentadienyl) ruthenium (Ru(DMPD)₂), 4-dimethylpentadienyl) (methylcyclopentadienyl) ruthenium (Ru(DMPD)(MeCp)), or (ethylcyclopentadienyl) ruthenium (Ru(EtCp)₂).

12. The method of claim 1, wherein the depositing comprises:
exposing the seed layer to Ru₃(CO)₁₂ and CO carrier gas.

13. The method of claim 1, wherein the forming bulk Cu metal comprises:
performing a Cu plating process.

14. The method of claim 1, wherein the forming bulk Cu metal comprises:
depositing a Cu seed layer onto the Ru barrier film; and
performing a Cu plating process.

15. The method of claim 1, further comprising:
heat treating the bulk Cu metal at a temperature between about 100° C. and about 400° C. in the presence of H₂ or a combination of an inert gas and H₂.

16. The method of claim 1, wherein the substrate comprises a micro-feature opening formed within a dielectric material, and wherein the depositing bulk Cu metal comprises filling the micro-feature opening with the bulk Cu metal.

17. The method of claim 16, wherein the micro-feature opening comprises a via, a trench, or a combination thereof.

18. The method of claim 16, further comprising:
at least partially removing the chemisorbed seed layer and the Ru barrier film from a bottom of the micro-feature opening prior to the forming bulk Cu metal.

19. A method for forming an interconnect structure, the method comprising:
providing a substrate containing a micro-feature opening formed within a dielectric material, wherein the micro-feature opening comprises a via, a trench, or a combination thereof;
exposing the substrate to a TAIMATA precursor at a substrate temperature below about 250° C. to form a chemisorbed seed layer of partially decomposed TAIMATA on the substrate;
depositing a Ru barrier film on the chemisorbed seed layer by exposure to Ru₃(CO)₁₂ and CO carrier gas;
sputter depositing a Cu seed layer on the Ru barrier film; and
filling the micro-feature opening with bulk Cu metal by a Cu plating process.

20. The method of claim 19, further comprising:
at least partially removing the chemisorbed seed layer and the Ru barrier film from a bottom of the micro-feature opening prior to the sputter depositing.

21. An interconnect structure, comprising:
a substrate containing a micro-feature opening formed within a dielectric material;
a Ta-, Ti-, or W-containing seed layer of a partially decomposed Ta-, Ti-, or W-containing precursor in the micro-feature opening;
a Ru barrier film on the seed layer; and
bulk Cu metal filling the micro-feature opening.

22. The interconnect structure of claim 21, wherein the seed layer is a Ta-containing seed layer, and the Ta-containing precursor comprises Ta(NMe₂)₃(NCMe₂Et) (TAIMATA), Ta(NEt₂)₅(PDEAT), Ta(NMe₂)₅(PDMAT), Ta(NEtMe)₅(PEMAT), (tBuN)Ta(NMe₂)₃(TBTDMT), (tBuN)Ta(NEt₂)₃(TBTDET), (tBuN)Ta(NEtMe)₃(TBTEMT), (iPrN)Ta(NEt₂)₃(IPTDET), Ta(η⁵-C₅H₅)₂H₃, Ta(CH₂)(CH₃)(η⁵-C₅H₅)₂, Ta(η³-C₃H₅) (η⁵-C₅H₅)₂, Ta(CH₃)₃(η⁵-C₅H₅)₂, Ta(CH₃)₄(η⁵-C₅(CH₃)₅), Ta(η⁵-C₅(CH₃)₅)₂H₃, Ta₂(OEt)₁₀, Me₂NCH₂CH₂O)Ta(OEt)₄, TaCl₅, or TaF₅.

23. The interconnect structure of claim 21, wherein the seed layer is a Ti-containing seed layer, and the Ti-containing precursor comprises Ti(NEt₂)₄, (TDEAT), Ti(NMeEt)₄ (TEMAT), Ti(NMe₂)₄ (TDMAT). Ti(COCH₃)(η⁵-C₅H₅)₂Cl, Ti(η⁵-C₅H₅)Cl₂, Ti(η⁵-C₅H₅)Cl₃, Ti(η⁵-C₅H₅)₂Cl₂, Ti(η⁵-C₅(CH₃)₅)Cl₃, Ti(CH₃)(η⁵-C₅H₅)₂Cl, Ti(η⁵-C₉H₇)₂Cl₂, Ti((η⁵-C₅(CH₃)₅)₂Cl, Ti((η⁵-C₅(CH₃)₅)₂Cl₂, Ti(η⁵-C₅H₅)₂(μ-Cl)₂, Ti(η⁵-C₅H₅)₂(CO)₂, Ti(CH₃)₃(η⁵-C₅H₅), Ti(CH₃)₂(η⁵-C₅H₅)₂, Ti(CH₃)₄, Ti(η⁵-C₅H₅)(η⁷-C₇H₇), Ti(η⁵-C₅H₅)(η⁸-C₈H₈), Ti(C₅H₅)₂(η⁵-C₅H₅)₂, Ti((C₅H₅)₂)₂(η-H)₂, Ti(η⁵-C₅(CH₃)₅)₂, Ti(η⁵-C₅CH₃)₅)₂(H)₂, Ti(CH₃)₂(η⁵-C₅(CH₃)₅)₂, or TiCl₄.

24. The interconnect structure of claim 21, wherein the seed layer is a W-containing seed layer, and the W-containing precursor comprises W(CO)₆ or WF₆.

25. The interconnect structure of claim 21, wherein a thickness of the Ru barrier film is less than about 10 nm.

26. The interconnect structure of claim 21, wherein a thickness of the Ru barrier film is between about 2 nm and about 8 nm.

27. The interconnect structure of claim 21, wherein a thickness of the Ru barrier film is between about 3 nm and about 5 nm.

28. The interconnect structure of claim 21, wherein the micro-feature opening comprises a via, a trench, or a combination thereof.

29. The interconnect structure of claim 21, wherein the seed layer and the Ru barrier film are at least partially removed from the bottom of the micro-feature opening.
